(19) United States
(12) Patent Application Publication
(10) Pub. No.: US 2016/0300954 A1
(43) Pub. Date: Oct. 13, 2016

(54) THIN-FILM TRANSISTOR AND MANUFACTURING METHOD FOR SAME

(71) Applicant: JOLED INC., Tokyo (JP)

(72) Inventor: Atsushi SASAKI, Tokyo (JP)

(73) Assignee: JOLED INC., Tokyo (JP)

(21) Appl. No.: 15/100,384

(22) PCT Filed: Aug. 26, 2014
(86) PCT No.: PCT/JP2014/004370

§ 371 Date: May 31, 2016

(30) Foreign Application Priority Data
Dec. 2, 2013 (JP) 2013-249375

(51) Int. Cl. H01L 29/786; H01L 27/12; H01L 21/02; H01L 29/24; H01L 29/66

(52) U.S. Cl. CPC H01L 29/78606; H01L 29/78693; H01L 29/247; H01L 29/66969; H01L 21/02164; H01L 21/02252; H01L 27/1225; H01L 27/1255; H01L 27/3262

(57) ABSTRACT

A manufacturing method for a thin-film transistor includes: forming an oxide semiconductor film above a substrate; forming a silicon film on the oxide semiconductor film; and performing plasma oxidation on the silicon film to (i) form an oxidized silicon film and (ii) supply oxygen to the oxide semiconductor film.

### TECHNICAL FIELD

The present disclosure relates to a thin-film transistor and a manufacturing method for the same.

### BACKGROUND ART

Thin-film transistors (TFTs) are widely used as switching elements or drive elements in active-matrix display devices such as liquid-crystal display devices or organic electro-luminescent (EL) display devices.

In recent years, active research and development of a configuration that uses an oxide semiconductor, such as zinc oxide (ZnO), indium gallium oxide (InGaO), or indium gallium zinc oxide (InGaZnO), in a channel layer of a TFT have been underway. The TFT in which the oxide semiconductor is used in the channel layer is characterized by an OFF-state current being small and carrier mobility being high even in an amorphous state and by being able to be formed in a low-temperature process.

Conventionally, a technique of reducing the degradation in electrical characteristics by supplying oxygen to an oxide semiconductor layer of the TFT is known. For example, Patent Literatures (PTLs) 1 and 2 disclose techniques of supplying oxygen to an oxide semiconductor layer by treating a surface of the oxide semiconductor layer with plasma.

### CITATION LIST

### Patent Literature

[PTL 1] Japanese Unexamined Patent Application Publication No. 2012-004554

[PTL 2] Japanese Unexamined Patent Application Publication No. 2011-249019

### SUMMARY OF INVENTION

### Technical Problem

In the case of the above-noted conventional thin-film transistor, after the oxide semiconductor layer is formed, oxygen is supplied to the oxide semiconductor layer by plasma treatment during or after a process of forming an insulation layer that covers the oxide semiconductor layer. This allows a reduction in defects in a surface of the oxide semiconductor layer and an interface between the oxide semiconductor layer and the insulation layer.

However, a problem with the plasma treatment that is performed during the process of forming an insulation layer that covers the oxide semiconductor layer is that process control is difficult as there is a risk of damaging the surface of the oxide semiconductor layer. Furthermore, a problem with the plasma treatment that is performed after the process of forming the insulation layer is that a certain length of processing time is required to supply oxygen to the oxide semiconductor layer because the oxygen needs to diffuse through the insulation layer.

Thus, the present disclosure provides a thin-film transistor having electrical characteristics the degradation of which is sufficiently reduced as a result of reduced damage to an oxide semiconductor surface in plasma treatment and efficiently supplying oxygen to an oxide semiconductor layer, and also provides a manufacturing method for the thin-film transistor.

### Solution to Problem

In order to solve the aforementioned problems, a manufacturing method for a thin-film transistor according to an aspect of the present disclosure includes: forming an oxide semiconductor film above a substrate; forming a silicon film on the oxide semiconductor film; and performing plasma oxidation on the silicon film to (i) form an oxidized silicon film and supply oxygen to the oxide semiconductor film.

### Advantageous Effects of Invention

According to the present disclosure, it is possible to provide a thin-film transistor with electrical characteristics the degradation of which is sufficiently reduced, and to provide a manufacturing method for the thin-film transistor.

### BRIEF DESCRIPTION OF DRAWINGS

FIG. 1 is a cut-out perspective view of an organic EL display device according to Embodiment 1.

FIG. 2 is a circuit diagram schematically illustrating the configuration of a pixel circuit in an organic EL display device according to Embodiment 1.

FIG. 3 is a schematic diagram of a cross section of a thin-film transistor according to Embodiment 1.

FIG. 4A is a schematic diagram of a cross section of a thin-film transistor according to Embodiment 1 illustrating a manufacturing method.

FIG. 4B is a schematic diagram of a cross section of a thin-film transistor according to Embodiment 1 illustrating a manufacturing method.

FIG. 4C is a schematic diagram of a cross section of a thin-film transistor according to Embodiment 1 illustrating a manufacturing method.

FIG. 5 schematically illustrates the configuration of chambers that can be used for continuous film formation according to a variation of Embodiment 1.

FIG. 6 is a schematic diagram of a cross section of a thin-film transistor according to Embodiment 2.

FIG. 7A is a schematic diagram of a cross section of a thin-film transistor according to Embodiment 2 illustrating a manufacturing method.

FIG. 7B is a schematic diagram of a cross section of a thin-film transistor according to Embodiment 2 illustrating a manufacturing method.

FIG. 7C is a schematic diagram of a cross section of a thin-film transistor according to Embodiment 2 illustrating a manufacturing method.

### DESCRIPTION OF EMBODIMENTS

### Outline of Present Disclosure

A manufacturing method for a thin-film transistor according to the present disclosure includes: forming an oxide semiconductor film above a substrate; forming a silicon film on the oxide semiconductor film; and performing plasma oxidation on the silicon film to (i) form an oxidized silicon film and (ii) supply oxygen to the oxide semiconductor film.

With this, the oxidized silicon film formed by plasma oxidation protects a surface of an oxide semiconductor from damage due to plasma, and prevents the oxide semiconductor film supplied with oxygen by plasma oxidation from being exposed to the air. Such a reduction in the occurrence of damage due to plasma and a reduction in oxygen loss allow a reduction in degradation of properties of the oxide semiconductor film. Therefore, it is possible to decrease the resistance reduction, etc., of the oxide semiconductor film. Thus, according to the manufacturing method for a thin-film transistor according to the present embodiment, it is possible to manufacture a thin-film transistor having less degraded electrical characteristics.

Furthermore, for example, in the manufacturing method for a thin-film transistor according to the present disclosure, in the forming of the silicon film, the silicon film may be formed by sputtering.

Since the plasma used in the sputtering does not contain hydrogen, it is possible to prevent hydrogen from diffusing in the oxide semiconductor film. Specifically, the silicon film is formed by sputtering typically using a noble gas element such as argon or krypton as an introduced gas. This means that since a gas containing hydrogen is not used as the introduced gas, it is possible to prevent hydrogen from diffusing in the oxide semiconductor film and thus reduce the degradation in electrical characteristics.

Furthermore, for example, in the manufacturing method for a thin-film transistor according to the present disclosure, in the forming of the oxide semiconductor film and in the forming of the silicon film, the oxide semiconductor film and the silicon film may be formed in a same vacuum system.

With this, the oxide semiconductor film and the silicon film are formed in the same vacuum system, and thus the interface between the oxide semiconductor film and the silicon film can be kept clean. Therefore, the degradation in electrical characteristics can further be reduced

Furthermore, for example, in the manufacturing method for a thin-film transistor according to the present disclosure, the silicon film may have a thickness of 5 nm or less.

With this, the time required for the plasma oxidation can be shortened, and thus it is possible to reduce the manufacturing cost.

Furthermore, for example, in the manufacturing method for a thin-film transistor according to the present disclosure, the silicon film may have a thickness of 2 nm or more.

With this, it is possible to form an oxidized silicon film having a thickness sufficient to prevent the oxide semiconductor film supplied with oxygen by the plasma oxidation from being exposed to the air.

Note that a range expressed as “A to B” herein means the range of A or more and B or less. For example, “the thickness of the silicon film is 2 nm to 5 nm” means “the thickness of the silicon film is 2 nm or more and 5 nm or less.”

Furthermore, for example, in the manufacturing method for a thin-film transistor according to the present disclosure, in the performing of the plasma oxidation, the silicon film may be oxidized with surface wave plasma or capacitively coupled plasma having an excitation frequency of 27 MHz or more.

An advantage with the surface wave plasma or the capacitively coupled plasma having an excitation frequency of 27 MHz or more is that this makes it possible to generate highly-concentrated oxygen radicals, resulting in that the damage due to ion injection to a substrate to be processed is small. Thus, it is possible to effectively supply oxygen to the oxide semiconductor film while reducing damage to the oxide semiconductor film.

Furthermore, for example, the manufacturing method for a thin-film transistor according to the present disclosure may further include: forming a resist on the oxidized silicon film, the resist being patterned; forming a silicon oxide layer by dry-etching the oxidized silicon film using the resist as a mask, the silicon oxide layer being patterned; wet-etching the oxide semiconductor film using the resist and the silicon oxide layer as a mask; performing ashing to cause an edge of the resist to retreat; and dry-etching the silicon oxide layer using the resist having a retreated edge as a mask.

With this, it is possible to remove a protruding portion of the silicon oxide layer generated by the wet-etching of the oxide semiconductor film.

Furthermore, for example, in the manufacturing method for a thin-film transistor according to the present disclosure, the oxide semiconductor film may be a transparent amorphous oxide semiconductor.

Furthermore, for example, in the manufacturing method for a thin-film transistor according to the present disclosure, the oxide semiconductor film may be InGaZnO.

A thin-film transistor according to the present disclosure includes: a substrate; an oxide semiconductor layer formed above the substrate; and a silicon oxide layer formed on the oxide semiconductor layer, wherein the silicon oxide layer is formed by plasma oxidation of a silicon film formed on the oxide semiconductor layer, and the oxide semiconductor layer contains oxygen supplied by the plasma oxidation.

Hereinafter, an embodiment of a thin-film transistor, a manufacturing method for the same, and an organic EL display device including a thin-film transistor will be described with reference to the Drawings. Note that each embodiment described below shows a specific preferred example of the present disclosure. Therefore, the numerical values, shapes, materials, structural elements, arrangement and connection of the structural elements, steps, the processing order of the steps, etc., shown in the following embodiments are mere examples, and are not intended to limit the present disclosure. Consequently, among the structural elements in the following embodiment, elements not recited in any one of the independent claims which indicate the broadest concepts of the present disclosure are described as arbitrary structural elements.

Note that the respective figures are schematic diagrams and are not necessarily precise illustrations. Additionally, components that are essentially the same share the same reference numerals in the respective figures, and overlapping explanations thereof are omitted or simplified.

### Embodiment 1

### Organic EL Display Device

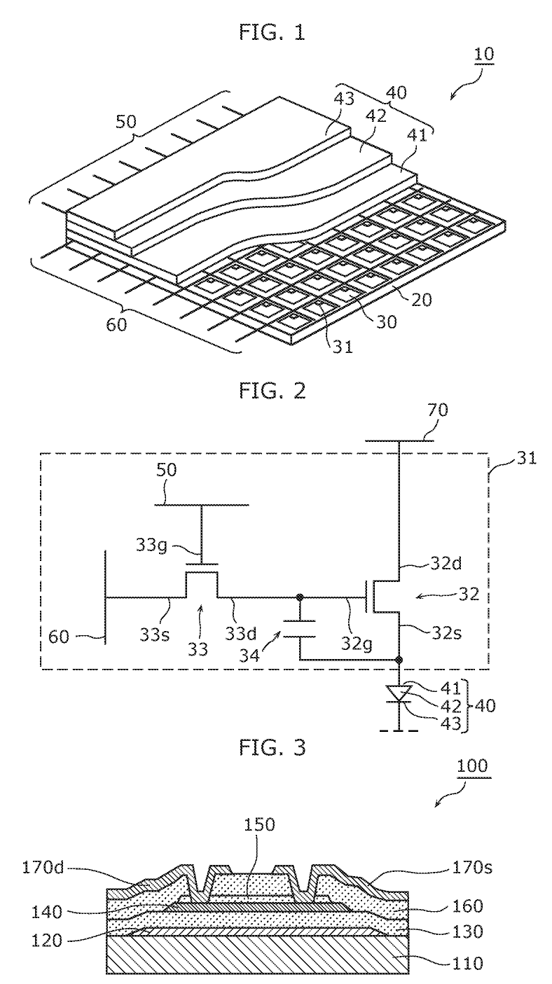

First, the configuration of an organic EL display device 10 according to the present embodiment will be described with reference to FIG. 1. FIG. 1 is a cut-out perspective view of an organic EL display device according to the present embodiment.

As illustrated in FIG. 1, the organic EL display device 10 includes a stacked structure of: a TFT substrate (TFT array substrate) 20 in which plural thin-film transistors are disposed; and organic EL elements (light-emitting units) 40 each including an anode 41 which is a lower electrode, an EL layer 42 which is a light-emitting layer including an organic material, and a cathode 43 which is a transparent upper electrode.

A plurality of pixels 30 are arranged in a matrix in the TFT substrate 20, and a pixel circuit 31 is included in each pixel 30.

Each of the organic EL elements 40 is formed corresponding to a different one of the pixels 30, and control of the light emission of the organic EL element 40 is performed according to the pixel circuit 31 included in the corresponding pixel 30. The organic EL elements 40 are formed on an interlayer insulating film (planarizing film) formed to cover the thin-film transistors.

Moreover, the organic EL elements 40 have a configuration in which the EL layer 42 is disposed between the anode 41 and the cathode 43. Furthermore, a hole transport layer is formed stacked between the anode 41 and the EL layer 42, and an electron transport layer is formed stacked between the EL layer 42 and the cathode 43. Note that other organic function layers may be formed between the anode 41 and the cathode 43.

Each pixel 30 is driven by its corresponding pixel circuit 31. Moreover, in the TFT substrate 20, a plurality of gate lines (scanning lines) 50 are disposed along the row direction of the pixels 30, a plurality of source lines (signal lines) 60 are disposed along the column direction of the pixels 30 to cross with the gate lines 50, and a plurality of power supply lines (not illustrated in FIG. 1) are disposed parallel to the source lines 60. The pixels 30 are partitioned from one another by the crossing gate lines 50 and source lines 60, for example.

The gate lines 50 are connected, on a per-row basis, to the gate electrode of the thin-film transistors operating as switching elements included in the respective pixel circuits 31. The source lines 60 are connected, on a per-column basis, to the source electrode of the thin-film transistors operating as switching elements included in the respective pixel circuits 31. The power supply lines are connected, on a per-column basis, to the drain electrode of the thin-film transistors operating as driver elements included in the respective pixel circuits 31.

Here, the circuit configuration of the pixel circuit 31 in each pixel 30 will be described with reference to FIG. 2. FIG. 2 is a circuit diagram schematically illustrating the configuration of a pixel circuit in an organic EL display device according to the present embodiment.

As illustrated in FIG. 2, the pixel circuit 31 includes a thin-film transistor 32 that operates as a driver element, a thin-film transistor 33 that operates as a switching element, and a capacitor 34 that stores data to be displayed by the corresponding pixel 30. In the present embodiment, the thin-film transistor 32 is a driver transistor for driving the organic EL elements 40, and the thin-film transistor 33 is a switching transistor for selecting the pixel 30.

The thin-film transistor 32 includes: a gate electrode 32g connected to a drain electrode 33d of the thin-film transistor 33 and one end of the capacitor 34; a drain electrode 32d connected to the power supply line 70; a source electrode 32s connected to the other end of the capacitor 34 and the anode 41 of the organic EL element 40; and a semiconductor film (not illustrated in the Drawings). The thin-film transistor 32 supplies current corresponding to data voltage held in the capacitor 34 from the power supply line 70 to the anode 41 of the organic EL elements 40 via the source electrode 32s. With this, in the organic EL elements 40, drive current flows from the anode 41 to the cathode 43 whereby the EL layer 42 emits light.

The thin-film transistor 33 includes: a gate electrode 33g connected to the gate line 50; a source electrode 33s connected to the source line 60; a drain electrode 33d connected to one end of the capacitor 34 and the gate electrode 32g of the thin-film transistor 32; and a semiconductor film (not illustrated in the Drawings). When a predetermined voltage is applied to the gate line 50 and the source line 60 connected to the thin-film transistor 33, the voltage applied to the source line 60 is held as data voltage in the capacitor 34.

Note that the organic EL display device 10 having the above-described configuration uses the active-matrix system in which display control is performed for each pixel 30 located at the cross-point between the gate line 50 and the source line 60. With this, the thin-film transistors 32 and 33 of each pixel 30 (of each of subpixels R, G, and B) cause the corresponding organic EL element 40 to selectively emit light, whereby a desired image is displayed.

[Thin-Film Transistor]

Hereinafter, the thin-film transistor according to the present embodiment will be described with reference to FIG. 3. Note that the thin-film transistor according to the present embodiment is a bottom-gate and channel protective thin-film transistor.

FIG. 3 is a schematic diagram of a cross section of a thin-film transistor 100 according to the present embodiment.

As illustrated in FIG. 3, the thin-film transistor 100 according to the present embodiment includes a substrate 110, a gate electrode 120, a gate insulating layer 130, an oxide semiconductor layer 140, a silicon oxide layer 150, a channel protective layer 160, a source electrode 170s, and a drain electrode 170d.

The thin-film transistor 100 is, for example, a thin-film transistor 32 or 33 illustrated in FIG. 2. This means that the thin-film transistor 100 can be used as a driver transistor or a switching transistor.

In the case where the thin-film transistor 100 is the thin-film transistor 32, the gate electrode 120 corresponds to the gate electrode 32g, the source electrode 170s corresponds to the source electrode 32s, and the drain electrode 170d corresponds to the drain electrode 32d. In the case where the thin-film transistor 100 is the thin-film transistor 33, the gate electrode 120 corresponds to the gate electrode 33g, the source electrode 170s corresponds to the source electrode 33s, and the drain electrode 170d corresponds to the drain electrode 33d.

The substrate 110 is a substrate configured from an electrically insulating material. For example, the substrate 110 is a substrate configured from a glass material such as alkali-free glass, quartz glass, or high-heat resistant glass; a resin material such as polyethylene, polypropylene, or polyimide; a semiconductor material such as silicon or gallium arsenide; or a metal material such as stainless steel coated with an insulating layer.

Note that the substrate 110 may be a flexible substrate such as a resin substrate. In this case, the thin-film transistor substrate 100 can be used as a flexible display.

The gate electrode 120 is formed in a predetermined shape, on the substrate 110. The thickness of the gate electrode 120 is, for example, 20 nm to 500 nm.

The gate electrode 120 is an electrode configured from a conductive material. For example, for the material of the gate electrode 120, it is possible to use a metal such as molybdenum, aluminum, copper, tungsten, titanium, manganese, chromium, tantalum, niobium, silver, gold, platinum, palladium, indium, nickel, neodymium, etc.; a metal alloy; a conductive metal oxide such as indium tin oxide (ITO), aluminum doped zinc oxide (AZO), gallium doped zinc oxide (GZO), etc.; or a conductive polymer such as polythiophene, polyacetylene, etc. Furthermore, the gate electrode 120 may have a multi-layered structure obtained by stacking these materials.

The gate insulating layer 130 is formed on the gate electrode 120. Specifically, the gate insulating layer 130 is formed on the gate electrode 120 and the substrate 110 so as to cover the gate electrode 120. The thickness of the gate insulating layer 130 is, for example, 50 nm to 300 nm.

The gate insulating layer 130 is configured from an electrically insulating material. For example, the gate insulating layer 130 is a single-layered film, such as an oxidized silicon film, a silicon nitride film, a silicon oxynitride film, an aluminum oxide film, a tantalum oxide film, or a hafnium oxide film, or a stacked film thereof.

The oxide semiconductor layer 140 is a channel layer of the thin-film transistor 100, and is formed above the substrate 110 so as to be opposite the gate electrode 120. Specifically, the oxide semiconductor layer 140 is formed on the gate insulating layer 130, at a position opposite the gate electrode 120. For example, the oxide semiconductor layer 140 is formed in the shape of an island on the gate insulating layer 130 above the gate electrode 120. The thickness of the oxide semiconductor layer 140 is, for example, 20 nm to 200 nm.

An oxide semiconductor material containing at least one from among indium (In), gallium (Ga), and zinc (Zn) is used for the material of the oxide semiconductor layer 140. For example, the oxide semiconductor layer 140 is configured from a transparent amorphous oxide semiconductor (TAOS) such as amorphous indium gallium zinc oxide (InGaZnO:IGZO).

The In:Ga:Zn ratio is, for example, approximately 1:1:1. Furthermore, although the In:Ga:Zn ratio may be in the range of 0.8 to 1.2:0.8 to 1.2:0.8 to 1.2, the ratio is not limited to this range.

Note that a thin-film transistor having a channel layer configured from a transparent amorphous oxide semiconductor has high carrier mobility, and is suitable for a large screen and high-definition display device. Furthermore, since a transparent amorphous oxide semiconductor allows low-temperature film-forming, a transparent amorphous oxide semiconductor can be easily formed on a flexible substrate of plastic or film, etc.

The oxide semiconductor layer 140 contains oxygen supplied thereto by plasma oxidation. For example, as will be described below, the oxide semiconductor layer 140 is supplied with oxygen by plasma oxidation, from the silicon oxide layer 150 side. Thus, a region of the oxide semiconductor layer 140 that faces the silicon oxide layer 150, specifically, a back channel region, contains oxygen supplied by the plasma oxidation. With this, it is possible to reduce oxygen loss from the oxide semiconductor layer 140.

The silicon oxide layer 150 is formed on the oxide semiconductor layer 140 by plasma oxidation of a silicon film formed on the oxide semiconductor layer 140. The thickness of the silicon oxide layer 150 is, for example, 2 nm to 5 nm.

Furthermore, portions of the silicon oxide layer 150 are through-holes. This means that the silicon oxide layer 150 has contact holes for exposing portions of the oxide semiconductor layer 140. The oxide semiconductor layer 140 is connected to the source electrode 170s and the drain electrode 170d via the opening portions (the contact holes).

Note that as illustrated in FIG. 3, an end of the oxide semiconductor layer 140 is located beyond the silicon oxide layer 150. Stated differently, the area of the silicon oxide layer 150 is smaller than the area of the oxide semiconductor layer 140 in a plan view.

The channel protective layer 160 is formed on the silicon oxide layer 150. For example, the channel protective layer 160 is formed on the silicon oxide layer 150, an end of the oxide semiconductor layer 140, and the gate insulating layer 130 so as to cover the silicon oxide layer 150 and the end of the oxide semiconductor layer 140. The thickness of the channel protective layer 160 is, for example, 50 nm to 500 nm.

Furthermore, portions of the channel protective layer 160 are through-holes. This means that the channel protective layer 160 has contact holes for exposing the portions of the oxide semiconductor layer 140. These contact holes are continuous to the contact holes formed in the silicon oxide layer 150.

The channel protective layer 160 is configured from an electrically insulating material. For example, the channel protective layer 160 is a film configured from an inorganic material, such as an oxidized silicon film, a silicon nitride film, a silicon oxynitride film, or an aluminum oxide film, or a single-layered film such as a film configured from an inorganic material containing silicon, oxygen, and carbon, or a stacked film thereof.

The source electrode 170s and the drain electrode 170d are formed in a predetermined shape, on the channel protective layer 160. Specifically, the source electrode 170s and the drain electrode 170d are connected to the oxide semiconductor layer 140 via the contact holes formed in the silicon oxide layer 150 and the channel protective layer 160, and are arranged opposing each other on the channel protective layer 160, by being separated in the horizontal direction along the substrate. The thickness of each of the source electrode 170s and the drain electrode 170d is, for example, 100 nm to 500 nm.

The source electrode 170s and the drain electrode 170d are electrodes configured from a conductive material. For example, a material that is the same as the material of the gate electrode 120 may be used for the source electrode 170s and the drain electrode 170d.

As described above, the thin-film transistor 100 according to the present embodiment includes the silicon oxide layer 150 having a thickness of 2 nm to 5 nm on the oxide semiconductor layer 140. The silicon oxide layer 150 is formed by oxidizing the silicon layer by plasma oxidation for supplying oxygen to the oxide semiconductor layer 140.

The silicon oxide layer 150 protects a surface of the oxide semiconductor layer 140 from damage due to plasma, and prevents the oxide semiconductor layer 140 supplied with oxygen by plasma oxidation from being exposed to the air. Such a reduction in the occurrence of damage due to plasma and a reduction in oxygen loss allow a reduction in degradation of properties of the oxide semiconductor layer 140. Therefore, it is possible to decrease the resistance reduction, etc., of the oxide semiconductor layer 140. Thus, the thin-film transistor 100 according to the present embodiment has less degraded electrical characteristics.

[Manufacturing Method for Thin-Film Transistor]

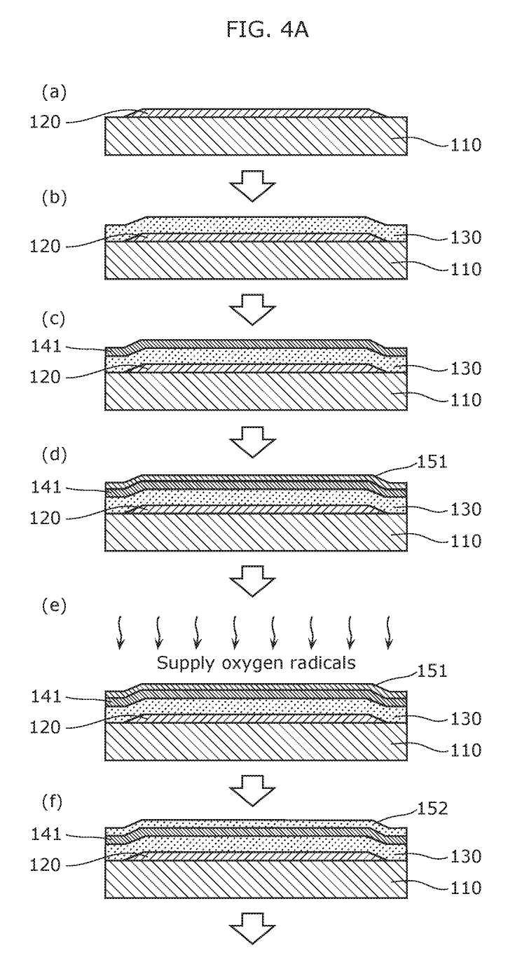

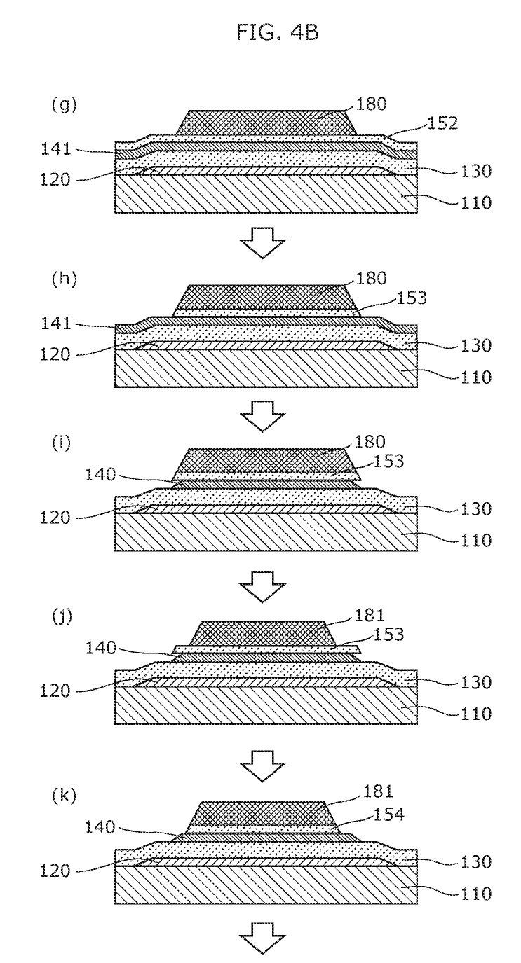

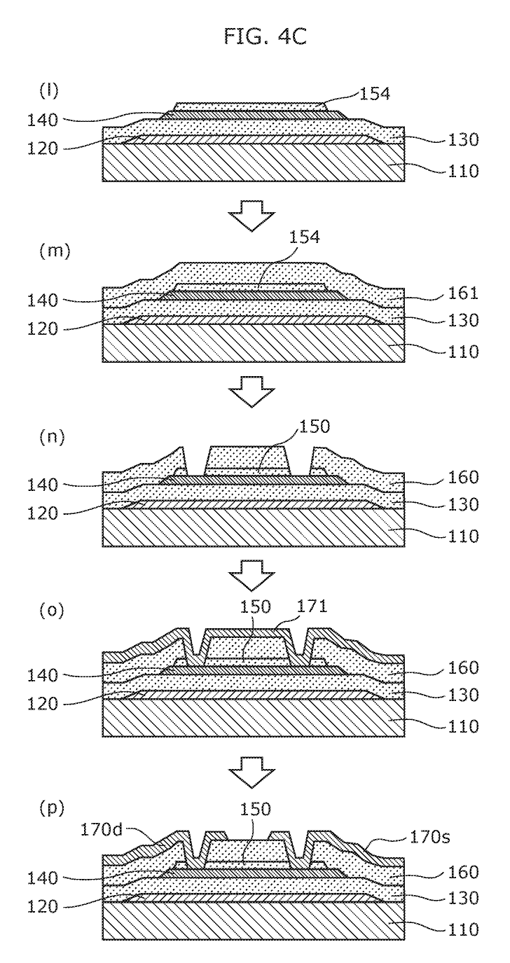

Next, a manufacturing method for a thin-film transistor according to the present embodiment will be described with reference to FIG. 4A to FIG. 4C. FIG. 4A to FIG. 4C are each a schematic diagram of a cross section of the thin-film transistor 100 according to the present embodiment illustrating a manufacturing method.

First, as illustrated in (a) of FIG. 4A, the substrate 110 is prepared, and the gate electrode 120 of a predetermined shape is formed above the substrate 110. For example, a metal film is formed on the substrate 110 by sputtering, and the metal film is processed by photolithography and wet etching to form the gate electrode 120 of the predetermined shape.

Specifically, first, a glass substrate is prepared as the substrate 110, and a molybdenum film (a Mo film) and a copper film (Cu film) are formed in sequence on the substrate 110 by sputtering. The total thickness of the Mo film and the Cu film is, for example, 20 nm to 500 nm. The Mo film and the Cu film are patterned by photolithography and wet etching to form the gate electrode 120. Note that the wet-etching of the Mo film and the Cu film can be performed using a mixed chemical solution of a hydrogen peroxide solution (H₂O₂) and organic acid, for example.

Next, as illustrated in (b) of FIG. 4A, the gate insulating layer 130 is formed above the substrate 110. For example, the gate insulating layer 130 is formed on the substrate 110 and the gate electrode 120 by plasma chemical vapor deposition (CVD).

Specifically, the gate insulating layer 130 is formed by forming a silicon nitride film and an oxidized silicon film in sequence by the plasma chemical vapor deposition (CVD) on the substrate 110 so as to cover the gate electrode 120. The thickness of the gate insulating layer 130 is, for example, 50 nm to 300 nm.

The silicon nitride film can be formed, for example, using silane gas (SiH₄), ammonium gas (NH₃), and nitrogen gas (N₂) as introduced gases. The oxidized silicon film can be formed, for example, using silane gas (SiH₄) and nitrous oxide gas (N₂O) as introduced gases.

Next, as illustrated in (c) of FIG. 4A, an oxide semiconductor film 141 is formed above the substrate 110, at a position opposite the gate electrode 120. For example, the oxide semiconductor film 141 is formed on the gate insulating layer 130 by sputtering. The thickness of the oxide semiconductor layer 141 is, for example, 20 nm to 200 nm.

Specifically, an amorphous InGaZnO film is formed on the gate insulating layer 130 by sputtering in an oxygen and argon (Ar) mixed gas atmosphere using a target material having an In:Ga:Zn composition ratio of 1:1:1.

Next, as illustrated in (d) of FIG. 4A, a silicon film 151 is formed on the oxide semiconductor film 141. For example, the silicon film 151 is formed on the oxide semiconductor film 141 by sputtering so as to have a thickness of 2 nm to 5 nm. The sputtering is performed, for example, under the following condition: the target material is silicon; the introduced gas is an argon (Ar) or krypton (Kr) gas; the pressure is 0.1 Pa to 1.0 Pa; and the power density is 0.03 W/cm² to 0.11 W/cm² (the input electric power is 2 kW to 6 kW).

Next, as illustrated in (e) of FIG. 4A, plasma oxidation is performed on the silicon film 151. As a result of the plasma oxidation of the silicon film 151, an oxidized silicon film 152 is formed and the oxide semiconductor film 141 is supplied with oxygen (oxygen radicals) as illustrated in (f) of FIG. 4A,

Specifically, the silicon film 151 is oxidized with surface wave plasma or capacitively coupled plasma (VHF plasma) having an excitation frequency of 27 MHz or more. The excitation frequency of the surface wave plasma is, for example, 2.45 GHz, 5.8 GHz, or 22.125 GHz,

An advantage with the surface wave plasma or the capacitively coupled plasma having an excitation frequency of 27 MHz or more is that this makes it possible to generate highly-concentrated oxygen radicals, resulting in that the damage due to ion injection to a substrate to be processed is small. In other words, it is possible to effectively supply oxygen to the oxide semiconductor film 141 while reducing damage to the oxide semiconductor film 141.

Note that when the silicon film 151 is oxidized with the surface wave plasma, the rate of increase in thickness of an oxidized film thereof is limited by the oxygen diffusion rate. Specifically, the oxidized silicon film that is being formed increases in thickness in proportion to the square root of time.

Therefore, an increase in thickness of the silicon film 151 leads to an increase in the time required to form the oxidized silicon film 152 by plasma oxidation, causing problems such as an increase in the manufacturing cost. Accordingly, the thickness of the silicon film 151 is set to 2 nm to 5 nm, for example, to allow for short plasma oxidation (for example, for about several tens of seconds to 10 minutes) to supply oxygen to the oxide semiconductor film 141. As just described, the time required for the plasma oxidation can be shortened, and thus it is possible to reduce the manufacturing cost.

Next, as illustrated in (g) of FIG. 4B, a resist 180 patterned in a predetermined shape is formed on the oxidized silicon film 152. The resist 180 is patterned by photolithography. For example, the thickness of the resist 180 is about 2 μm.

Specifically, the resist 180 is formed using a photoresist made of a polymer containing photosensitive functional molecules. The photoresist is applied onto the oxidized silicon film 152, followed by pre-bake, exposure, development, and post-bake, to form the patterned resist 180.

Next, as illustrated in (h) of FIG. 4B, a patterned silicon oxide layer 153 is formed on the oxide semiconductor film 141. Specifically, the oxidized silicon film 152 is dry-etched using the resist 180 as a mask to form the patterned silicon oxide layer 153.

For example, reactive ion etching (RIE) can be used as the dry etching. At this time, for example, carbon tetrafluoride (CF₄) and oxygen gas (O₂) can be used as etching gases. Parameters such as the gas flow rate, pressure, applied power, and frequency are set as appropriate depending on the substrate size, the thickness of the film to be etched, etc.

Next, as illustrated in (i) of FIG. 4B, the patterned oxide semiconductor layer 140 is formed on the gate insulating layer 130. Specifically, the oxide semiconductor film 141 is wet-etched using the resist 180 and the silicon oxide layer 153 as a mask to form the oxide semiconductor layer 140.

Specifically, the amorphous InGaZnO film formed on the gate insulating layer 130 is wet-etched to form the oxide semiconductor layer 140. The wet-etching of InGaZnO can be performed using a mixed chemical solution of, for example, phosphoric acid (H₃PO₄), nitric acid (HNO₃), acetic acid (CH₃COOH), and water.

Note that the chemical solution for use in the wet etching flows under an end of the silicon oxide layer 153 and scrapes away an end of the oxide semiconductor layer 140 as illustrated in (i) of FIG. 4B. In other words, the end of the silicon oxide layer 153 is located outward beyond the oxide semiconductor layer 140 in a plan view.

Next, as illustrated in (j) of FIG. 4B, ashing is performed to cause the edge of the resist 180 to retreat. For example, when oxygen plasma is generated, the resist 180 binds to oxygen radicals contained in the plasma and evaporates. Therefore, a portion of the resist 180 exposed to the oxygen plasma, that is, a surface portion of the resist 180, is removed by evaporating, resulting in the edge of the resist 180 gradually retreating. Thus, the resist 180 is reduced in size by ashing.

A resist 181 having the retreated edge is formed on the silicon oxide layer 153 as just described. Note that the resist 180 is shrunk overall, and therefore the thickness of the resist 181 having the retreated edge is smaller than the thickness of the resist 180.

The length of time for ashing with the use of oxygen plasma is determined, for example, based on the width of the protruding portion of the silicon oxide layer 153. In other words, the time for ashing is determined so as to make the size of the shrunk resist 181 less than or equal to the size of the oxide semiconductor layer 140 in a plan view.

Next, as illustrated in (k) of FIG. 4B, a silicon oxide layer 154 is formed by dry-etching the silicon oxide layer 153 using the resist 181 having the retreated edge as a mask. Thus, it is possible to remove the protruding portion of the silicon oxide layer 153 generated by the wet-etching of the oxide semiconductor film 141 (see (i) of FIG. 4B).

Next, as illustrated in (l) of FIG. 4C, the resist 181 is removed. For example, the resist 181 is removed by ashing with the use of oxygen plasma. Specifically, ashing for a sufficiently long length of time as compared to that in reducing the size of the resist 180 allows the resist 181 to be removed.

Next, as illustrated in (m) of FIG. 4C, a channel protective film 161 is formed above the oxide semiconductor layer 140. For example, the channel protective film 161 is formed on the silicon oxide layer 154, the oxide semiconductor layer 140, and the gate insulating layer 130 so as to cover the silicon oxide layer 154 and the oxide semiconductor layer 140.

Specifically, an oxidized silicon film is formed over the entire surface by plasma CVD so that the channel protective layer 161 can be formed. The thickness of the oxidized silicon film is, for example, 50 nm to 500 nm. The oxidized silicon film can be formed, for example, using silane gas (SiH₄) and nitrous oxide gas (N₂O) as introduced gases.

Next, as illustrated in (n) of FIG. 4C, the channel protective film 161 and the silicon oxide layer 154 are patterned in a predetermined shape to form the patterned channel protective layer 160 and silicon oxide layer 150.

Specifically, contact holes are formed in the channel protective film 161 and the silicon oxide layer 154 so that portions of the oxide semiconductor layer 140 are exposed. For example, portions of the channel protective film 161 and the silicon oxide layer 154 are removed by etching, so as to form contact holes.

Specifically, portions of the channel protective film 161 and the silicon oxide layer 154 are etched by photolithography and dry etching to form contact holes on regions of the oxide semiconductor layer 140 that become a source-contact region and a drain-contact region. For example, when the channel protective film 161 is an oxidized silicon film, the reactive ion etching (RIE) can be used as the dry etching. At this time, for example, carbon tetrafluoride (CF₄) and oxygen gas (O₂) can be used as etching gases. Parameters such as the gas flow rate, pressure, applied power, and frequency are set as appropriate depending on the substrate size, the thickness of the film to be etched, etc.

Next, as illustrated in (o) of FIG. 4C, a metal film 171 is formed so as to connect to the oxide semiconductor layer 140 via the contact holes. Specifically, the metal film 171 is formed on the channel protective film 160 and inside the contact holes.

Specifically, the Mo film, the Cu film, and the CuMn film are formed in sequence on the channel protective layer 160 and inside the contact holes by sputtering to form the metal film 171. The thickness of the metal film 171 is, for example, 100 nm to 500 nm.

Next, as illustrated in (p) of FIG. 4C, the source electrode 170s and the drain electrode 170d are formed to be connected to the oxide semiconductor layer 140. For example, the source electrode 170s and the drain electrode 170d are formed in a predetermined shape on the channel protective layer 160 so as to fill the contact holes formed in the channel protective layer 160.

Specifically, the source electrode 170s and the drain electrode 170d are formed spaced apart from each other, on the channel protective layer 160 and inside the contact holes. More specifically, the metal film 171 is patterned by photolithography and wet etching, to form the source electrode 170s and the drain electrode 170d.

Note that the wet-etching of the Mo film, the Cu film, and the CuMn film can be performed using a mixed chemical solution of a hydrogen peroxide solution (H₂O₂) and organic acid, for example.

This is how the thin-film transistor 100 can be manufactured.

[Conclusion]

As described above, the manufacturing method for a thin-film transistor according to the present embodiment includes: forming the oxide semiconductor film 141 above the substrate 110; forming the silicon film 151 on the oxide semiconductor film 141; and performing plasma oxidation on the silicon film 151 to (i) form the oxidized silicon film 152 and (ii) supply oxygen to the oxide semiconductor film 141.

Thus, the oxidized silicon film 152 formed by plasma oxidation protects a surface of the oxide semiconductor film 141 from damage due to plasma, and prevents the oxide semiconductor film 141 supplied with oxygen by plasma oxidation from being exposed to the air. Such a reduction in the occurrence of damage due to plasma and a reduction in oxygen loss allow a reduction in degradation of properties of the oxide semiconductor film 141. In short, the oxidized silicon film 152 makes it possible to reduce process damage in the following film-forming process.

Note that when process damage occurs, the oxygen loss percentage of the oxide semiconductor film 141 increases. For example, a region having a high oxygen loss percentage has a high carrier percentage and therefore is more likely to have a parasitic current path. In other words, the region having a high oxygen loss percentage has reduced resistance.

As described above, the manufacturing method for a thin-film transistor according to the present embodiment makes it possible to reduce the oxygen loss, allowing the oxide semiconductor film 141 to have a reduced oxygen loss percentage. In other words, it is possible to reduce carrier sources in the oxide semiconductor film 141, and thus it is possible to decrease the resistance reduction, etc., of the oxide semiconductor film 141. Therefore, according to the present embodiment, the thin-film transistor 100 having less degraded electrical characteristics can be manufactured.

Although the silicon film 151 is formed on the oxide semiconductor film 141 after the oxide semiconductor film 141 is formed in the present embodiment, the oxide semiconductor film 141 and the silicon film 151 may be formed in the same vacuum system at this time. In other words, the oxide semiconductor film 141 and the silicon film 151 may be continuously formed.

The phrase “in the same vacuum system” means maintaining a plurality of vacuum chambers under substantially the same pressure, for example. Specifically, film formation in the same vacuum system means that films are formed without the target substrate being exposed under atmosphere pressure.

For example, a plurality of vacuum chambers may be connected via gate valves to allow the oxide semiconductor film 141 and the silicon film 151 to be formed in a continuous film-forming process performed inside a vacuum system including a unit that transports the substrate while the vacuum is maintained.

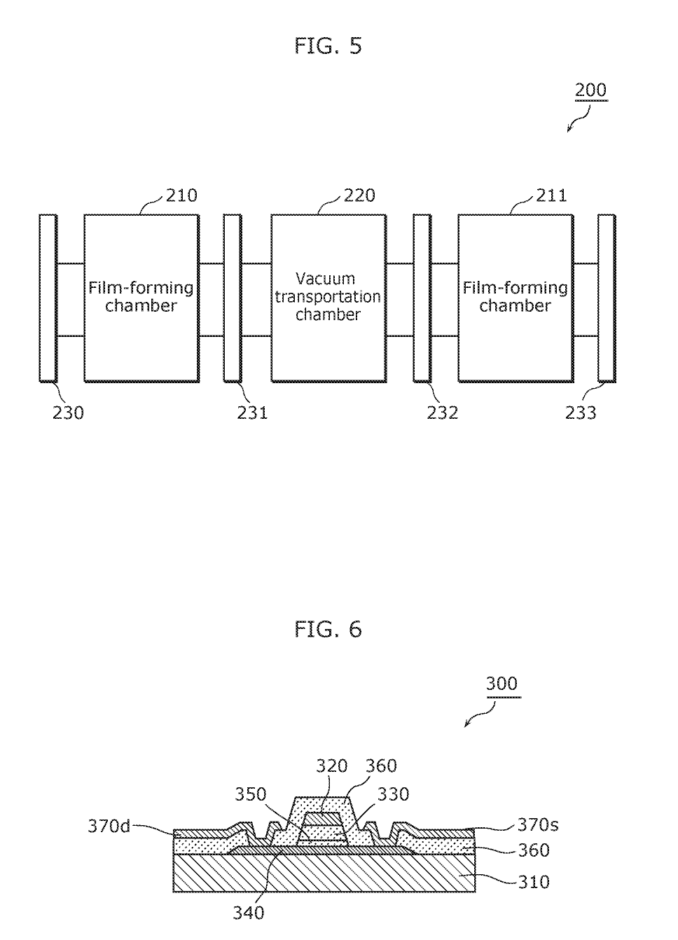

Specifically, a film-forming device 200 having a plurality of chambers as those illustrated in FIG. 5 can be used for the continuous film formation. FIG. 5 schematically illustrates the configuration of chambers that can be used for continuous film formation according to a variation of the present embodiment.

The film-forming device 200 illustrated in FIG. 5 is a multi-chamber film-forming device in which a plurality of chambers are connected via gate valves. The film-forming device 200 includes two film-forming chambers 210 and 211, a vacuum transportation chamber 220, and gate valves 230 to 233 provided between the respective chambers.

The film-forming chamber 210 is a film-forming chamber for forming the oxide semiconductor film 141. Therefore, the film-forming chamber 210 is, for example, a chamber for performing sputtering in an oxygen atmosphere using a target material having an In:Ga:Zn composition ratio of 1:1:1.

The film-forming chamber 211 is a film-forming chamber for forming the silicon film 151. Therefore, the film-forming chamber 211 is, for example, a chamber for performing sputtering in an Ar or Kr atmosphere using a target material that includes silicon.

The vacuum transportation chamber 220 is a chamber for transporting the substrate. The substrate is transported from the film-forming chamber 210 to the film-forming chamber 211 by a transportation arm or the like provided inside the vacuum transportation chamber 220.

The gate valves 230 to 233 are flapping valves. The gate valve 230 is opened to allow the substrate to be placed in the film-forming chamber 210. The gate valve 231 and the gate valve 232 are opened to allow the substrate to be transported from the film-forming chamber 210 to the film-forming chamber 211. The gate value 233 is opened to allow the substrate to be discharged from the film-forming chamber 211. The gate valves 230 to 233 are closed during sputtering in the film-forming chamber 210 and the film-forming chamber 211.

The film-forming chambers 210 and 211 are maintained in the same vacuum system as the vacuum transportation chamber 220. More specifically, these chambers are maintained in the same vacuum system after the substrate is placed in the film-forming chamber 210 until the substrate is discharged from the film-forming chamber 211.

This means that the oxide semiconductor film 141 and the silicon film 151 can be continuously formed without being exposed to the air. Therefore, the interface between the oxide semiconductor film 141 and the silicon film 151 can be kept clean. Thus, after the oxide semiconductor film 141 is formed, the silicon film 151 can be formed while the surface of the oxide semiconductor film 141 is kept clean.

At this time, the silicon film 151 is formed by sputtering in the Ar or Kr atmosphere in the present embodiment. Thus, since a gas containing hydrogen is not used, it is possible to reduce the occurrence of hydrogen diffusing in the oxide semiconductor film 141.

As described above, the plurality of film-forming chambers 210 and 211 can be connected via the gate valves 230 to 233 to allow the oxide semiconductor film 141 and the silicon film 151 to be formed in the continuous film-forming process performed inside a vacuum system including the vacuum transportation chamber 220 which transports the substrate while the vacuum is maintained. With this, the degradation in electrical characteristics of the oxide semiconductor film 141 can further be reduced.

Note that when the plurality of film-forming chambers 210 and 211 are connected in-line via the gate valves, the same vacuum system may be constituted without using the vacuum transportation chamber 220. Furthermore, instead of the plurality of vacuum chambers, a single vacuum chamber may be used for the continuous film formation. For example, the substrate is placed in the single vacuum chamber, and the target material, the introduced gas, and so on are changed so that the oxide semiconductor film 141 and the silicon film 151 can be continuously formed in the same vacuum system.

### Embodiment 2

Next, Embodiment 2 is described. The configuration of an organic EL display device according to the present embodiment is substantially the same as that of the organic EL display device 10 according to Embodiment 1; as such, descriptions thereof are omitted, and descriptions are given only for a thin-film transistor.

[Thin-Film Transistor]

Hereinafter, the thin-film transistor according to the present embodiment will be described. Note that the thin-film transistor according to the present embodiment is a top-gate thin-film transistor.

FIG. 6 is a schematic diagram of a cross section of a thin-film transistor 300 according to the present embodiment.

As illustrated in FIG. 6, the thin-film transistor 300 according to the present embodiment includes a substrate 310, a gate electrode 320, a gate insulating layer 330, an oxide semiconductor layer 340, a silicon oxide layer 350, an insulating layer 360, a source electrode 370s, and a drain electrode 370d.

The thin-film transistor 300 is, for example, the thin-film transistor 32 or 33 illustrated in FIG. 2. This means that the thin-film transistor 300 can be used as a driver transistor or a switching transistor.

In the case where the thin-film transistor 300 is the thin-film transistor 32, the gate electrode 320 corresponds to the gate electrode 32g, the source electrode 370s corresponds to the source electrode 32s, and the drain electrode 370d corresponds to the drain electrode 32d. In the case where the thin-film transistor 300 is the thin-film transistor 33, the gate electrode 320 corresponds to the gate electrode 33g, the source electrode 370s corresponds to the source electrode 33s, and the drain electrode 370d corresponds to the drain electrode 33d.

The substrate 310 is a substrate configured from an electrically insulating material. For example, the substrate 310 is a substrate configured from a glass material such as alkali-free glass, quartz glass, or high-heat resistant glass; a resin material such as polyethylene, polypropylene, or polyimide; a semiconductor material such as silicon or gallium arsenide; or a metal material such as stainless steel coated with an insulating layer.

Note that the substrate 310 may be a flexible substrate such as a resin substrate. In this case, the thin-film transistor substrate 300 can be used as a flexible display.

The gate electrode 320 is formed in a predetermined shape, above the substrate 310. For example, the gate electrode 320 is formed on the gate insulating layer 330, at a position opposite the oxide semiconductor layer 340. The material and thickness of the gate electrode 320 may be the same as those of the gate electrode 120 according to Embodiment 1.

The gate insulating layer 330 is formed between the gate electrode 320 and the oxide semiconductor layer 340. Specifically, the gate insulating layer 330 is formed on the silicon oxide layer 350. The gate insulating layer 330 is configured from an electrically insulating material. For example, the material and thickness of the gate insulating layer 330 may be the same as those of the gate insulating layer 130 according to Embodiment 1.

The oxide semiconductor layer 340 is a channel layer of the thin-film transistor 300, and is formed on the substrate 310, at a position opposite the gate electrode 320. For example, the oxide semiconductor layer 340 is formed in the shape of an island on the substrate 310. The material and thickness of the oxide semiconductor layer 340 may be the same as those of the oxide semiconductor layer 140 according to Embodiment 1.

The oxide semiconductor layer 340 contains oxygen supplied thereto by plasma oxidation. For example, as will be described below, the oxide semiconductor layer 340 is supplied with oxygen by the plasma oxidation, from the silicon oxide layer 350 side. Thus, a region of the oxide semiconductor layer 340 that faces the silicon oxide layer 350, specifically, a front channel region, contains oxygen supplied by the plasma oxidation. With this, it is possible to reduce oxygen loss from the oxide semiconductor layer 340.

The silicon oxide layer 350 is formed on the oxide semiconductor layer 340 by plasma oxidation of a silicon film formed on the oxide semiconductor layer 340. The thickness of the silicon oxide layer 350 is, for example, 2 nm to 5 nm.

The insulating layer 360 is formed on the substrate 310, the oxide semiconductor layer 340, and the gate electrode 320. For example, the insulating layer 360 is formed on the substrate 310, the oxide semiconductor layer 340, and the gate electrode 320 so as to cover the gate electrode 320 and the end of the oxide semiconductor layer 340. For example, the material and thickness of the insulating layer 360 may be the same as those of the channel protective layer 160 according to Embodiment 1.

Furthermore, portions of the insulating layer 360 are through-holes. This means that the insulating layer 360 has contact holes for exposing portions of the oxide semiconductor layer 340.

The source electrode 370s and the drain electrode 370d are formed in a predetermined shape, on the insulating layer 360. Specifically, the source electrode 370s and the drain electrode 370d are connected to the oxide semiconductor layer 340 via the contact holes formed in the insulating layer 360, and are arranged opposing each other on the insulating layer 360, by being separated in the horizontal direction along the substrate. The material and thickness of the source electrode 370s and the drain electrode 370d may be the same as those of the source electrode 170s and the drain electrode 170d according to Embodiment 1.

As described above, the thin-film transistor 300 according to the present embodiment includes the silicon oxide layer 350 having a thickness of 2 nm to 5 nm on the oxide semiconductor layer 340. The silicon oxide layer 350 is formed by oxidizing the silicon layer by plasma oxidation for supplying oxygen to the oxide semiconductor layer 340.

The silicon oxide layer 350 protects a surface of the oxide semiconductor layer 340 from damage due to plasma, and prevents the oxide semiconductor layer 340 supplied with oxygen by plasma oxidation from being exposed to the air. Such a reduction in the occurrence of damage due to plasma and a reduction in oxygen loss allow a reduction in degradation of properties of the oxide semiconductor layer 340. Therefore, it is possible to decrease the resistance reduction, etc., of the oxide semiconductor layer 340. Consequently, the thin-film transistor 300 according to the present embodiment has less degraded electrical characteristics.

Thus, the thin-film transistor 300 according to the present embodiment has less degraded electrical characteristics. Particularly, in the present embodiment, the resistance reduction of the front channel region can be decreased, and thus it is possible to further reduce the deterioration in electrical characteristics.

[Method for Manufacturing Thin-Film Transistor]

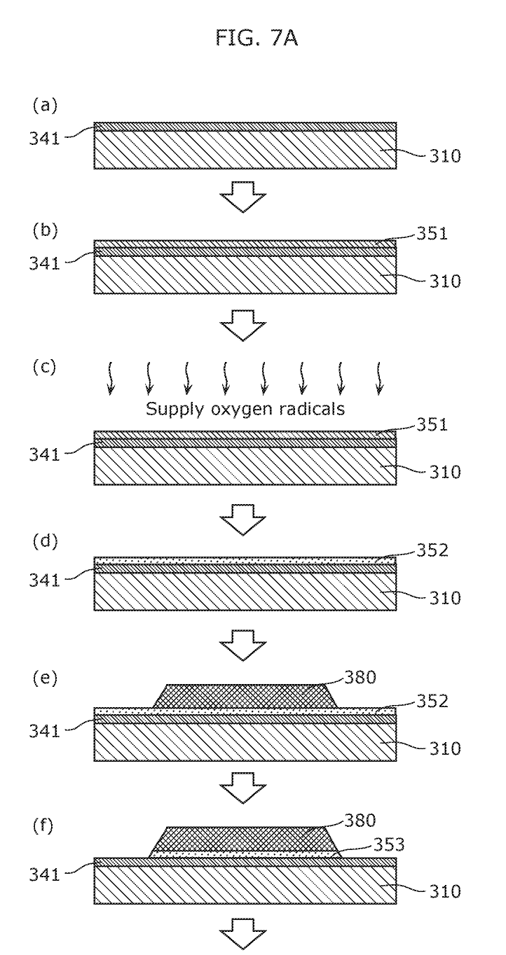

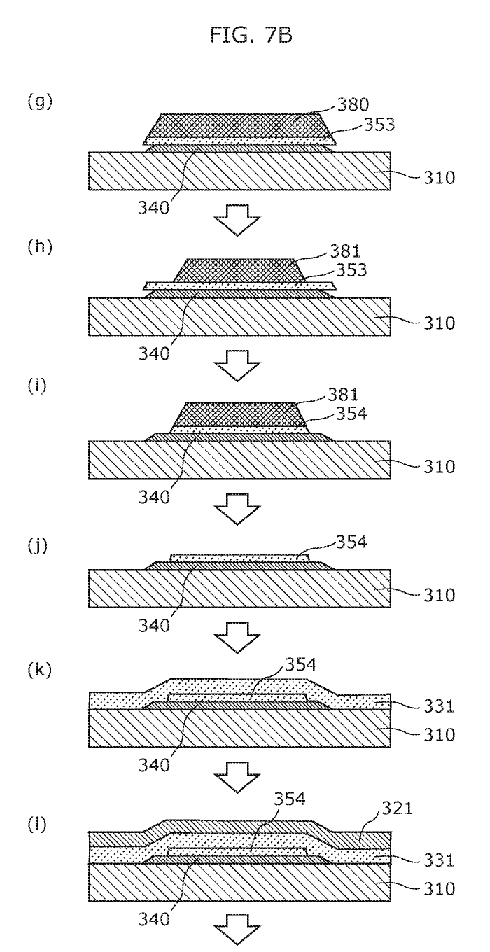

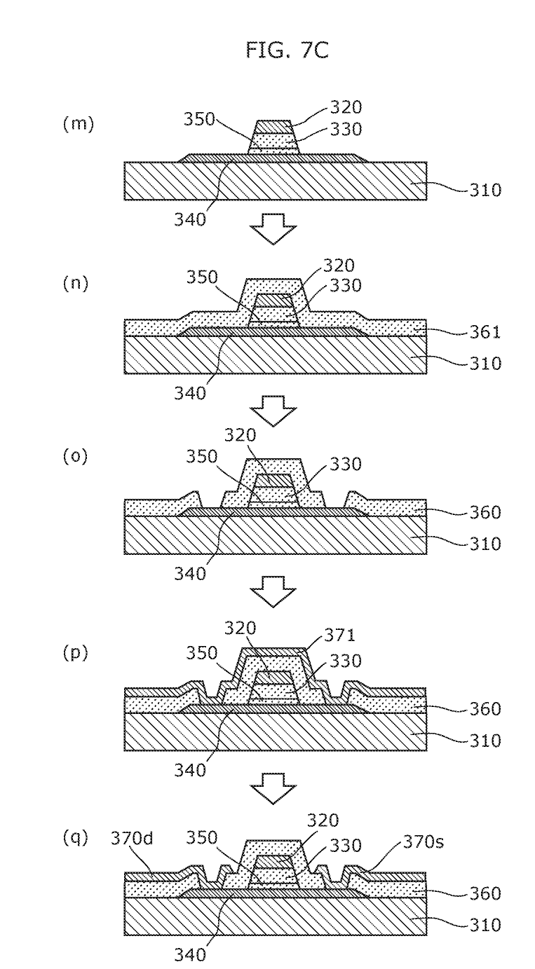

Next, a manufacturing method for a thin-film transistor according to the present embodiment will be described with reference to FIG. 7A to FIG. 7C. FIG. 7A to FIG. 7C are each a schematic diagram of a cross section of the thin-film transistor 300 according to the present embodiment illustrating a manufacturing method.

First, as illustrated in (a) of FIG. 7A, the substrate 310 is prepared, and an oxide semiconductor film 341 is formed on the substrate 310. For example, the oxide semiconductor film 341 is formed on the substrate 310 by sputtering. The condition for the sputtering is the same as that for forming the oxide semiconductor film 141 according to Embodiment 1, for example (see (c) of FIG. 4A).

Next, as illustrated in (b) of FIG. 7A, a silicon film 351 is formed on the oxide semiconductor film 341. For example, the silicon film 351 is formed on the oxide semiconductor film 341 by sputtering so as to have a thickness of 2 nm to 5 nm. The condition for the sputtering is the same as that for forming the silicon film 151 according to Embodiment 1, for example (see (d) of FIG. 4A).

Next, as illustrated in (c) of FIG. 7A, plasma oxidation is performed on the silicon film 351. As a result of the plasma oxidation of the silicon film 351, an oxidized silicon film 352 is formed and the oxide semiconductor film 341 is supplied with oxygen as illustrated in (d) of FIG. 7A. The condition for the plasma oxidation is the same as that for the plasma oxidation according to Embodiment 1, for example (see (e) and (f) of FIG. 4A). Thus, it is possible to effectively supply oxygen to the oxide semiconductor film 341 while reducing damage to the oxide semiconductor film 341.

Next, as illustrated in (e) of FIG. 7A, a resist 380 patterned in a predetermined shape is formed on the silicon oxide film 352. The resist 380 is patterned by photolithography. For the formation of the resist 380, the same method is used as for the formation of the resist 180 according to Embodiment 1, for example (see (g) of FIG. 4B).

Next, as illustrated in (f) of FIG. 7A, a patterned silicon oxide layer 353 is formed on the oxide semiconductor film 341. Specifically, the oxidized silicon film 352 is dry-etched using the resist 380 as a mask to form the patterned silicon oxide layer 353. The dry-etching of the oxidized silicon film 352 is performed in the same method as the dry-etching of the oxidized silicon film 152 according to Embodiment 1, for example (see (h) of FIG. 4B).

Next, as illustrated in (g) of FIG. 7B, the patterned oxide semiconductor layer 340 is formed on the substrate 310. Specifically, the oxide semiconductor film 341 is wet-etched using the resist 380 and the silicon oxide layer 353 as a mask to form the oxide semiconductor layer 340.

Specifically, the amorphous InGaZnO film formed on the substrate 310 is wet-etched to form the oxide semiconductor layer 340. The wet-etching of InGaZnO can be performed using a mixed chemical solution of, for example, phosphoric acid (H₃PO₄), nitric acid (HNO₃), acetic acid (CH₃COOH), and water.

Note that as in Embodiment 1, the chemical solution for use in the wet etching flows under an end of the silicon oxide layer 353 and scrapes away an end of the oxide semiconductor layer 340 as illustrated in (g) of FIG. 7B. In other words, the end of the silicon oxide layer 353 is located outward beyond the oxide semiconductor layer 340 in a plan view.

Next, as illustrated in (h) of FIG. 7B, ashing is performed to cause the edge of the resist 380 to retreat. More specifically, the resist 380 is reduced in size by ashing, to form on the silicon oxide layer 353 a resist 381 having a retreated edge. The ashing of the resist 380 for causing the edge thereof to retreat is performed in the same method as the ashing of the resist 180 according to Embodiment 1, for example (see (j) of FIG. 4B).

Next, as illustrated in (i) of FIG. 7B, a silicon oxide layer 354 is formed by dry-etching the silicon oxide layer 353 using the resist 381 having the retreated edge as a mask. Thus, it is possible to remove the protruding portion of the silicon oxide layer 353 generated by the wet-etching of the oxide semiconductor film 341 (see (g) of FIG. 7B).

Next, as illustrated in (j) of FIG. 7B, the resist 381 is removed. For example, the resist 381 is removed by ashing with the use of oxygen plasma. Specifically, ashing for a sufficiently long length of time as compared to that in reducing the size of the resist 380 allows the resist 381 to be removed.

Next, as illustrated in (k) of FIG. 7B, a gate insulating film 331 is formed on the silicon oxide layer 354. For example, the gate insulating film 331 is formed by plasma CVD on the silicon oxide layer 354, the oxide semiconductor layer 340, and the substrate 310 so as to cover the silicon oxide layer 354 and the end of the oxide semiconductor layer 340. For the formation of the gate insulating film 331, the same method is used as for the formation of the gate insulating layer 130 according to Embodiment 1, for example (see (b) of FIG. 4A).

Next, as illustrated in (l) of FIG. 7B, a metal film 321 is formed on the gate insulating film 331. For example, the metal film 321 is formed on the gate insulating film 331 by sputtering. Specifically, the Mo film and the Cu film are formed in sequence on the gate insulating film 331. The total thickness of the Mo film and the Cu film is, for example, 20 nm to 500 nm.

Next, as illustrated in (m) of FIG. 7C, the metal film 321, the gate insulating film 331, and the silicon oxide layer 354 are patterned to form the gate electrode 320, the gate insulating layer 330, the silicon oxide layer 350. For example, the metal film 321 is patterned by wet etching, and the gate insulating film 331 and the silicon oxide layer 354 are patterned by dry etching.

The wet-etching of the metal film 321 can be performed using a mixed chemical solution of a hydrogen peroxide solution (H₂O₂) and organic acid, for example. As the dry-etching of the gate insulating layer 331 and the silicon oxide layer 354, the reactive ion etching (RIE) can be used, for example. At this time, for example, carbon tetrafluoride (CF₄) and oxygen gas (O₂) can be used as etching gases. Parameters such as the gas flow rate, pressure, applied power, and frequency are set as appropriate depending on the substrate size, the thickness of the film to be etched, etc.

At this time, a portion of the oxide semiconductor layer 340 is exposed and is therefore subject to the influence of the dry etching. Specifically, the resistance of the exposed portion of the oxide semiconductor layer 340 is reduced. Therefore, the portion having reduced resistance can be used as a region that connects to the source electrode or the drain electrode; thus, good source contact and drain contact can be provided.

Next, as illustrated in (n) of FIG. 7C, an insulating film 361 is formed on the gate electrode 320 and the oxide semiconductor layer 340. For example, the insulating film 361 is formed on the substrate 310, the gate electrode 320, the oxide semiconductor layer 340 so as to cover the gate electrode 320 and the oxide semiconductor layer 340. For the formation of the insulating film 361, the same method is used for the formation of the channel protective film 161 according to Embodiment 1, for example (see (m) of FIG. 4C).

Next, as illustrated in (o) of FIG. 7C, the insulating film 361 is patterned in a predetermined shape to form the patterned insulating layer 360. Specifically, contact holes are formed in the insulating film 361 so that portions of the oxide semiconductor layer 340 are exposed. For example, portions of the insulating film 361 are removed by etching, so as to form contact holes. For the formation of the contact holes, the same method is used as for the formation of the contact holes in the channel protective film 161 according to Embodiment 1, for example (see (n) of FIG. 4C).

Next, as illustrated in (p) of FIG. 7C, a metal film 371 is formed so as to connect to the oxide semiconductor layer 340 via the contact holes. Specifically, the metal film 371 is formed on the insulating film 360 and inside the contact holes. For the formation of the metal film 371, the same method is used for the formation of the metal film 171 according to Embodiment 1, for example (see (o) of FIG. 4C).

Next, as illustrated in (q) of FIG. 7C, the source electrode 370s and the drain electrode 370d are formed to be connected to the oxide semiconductor layer 340. For example, the source electrode 370s and the drain electrode 370d are formed in a predetermined shape on the insulating layer 360 so as to fill the contact holes formed in the insulating layer 360. For the formation of the source electrode 370s and the drain electrode 370d, the same method is used as for the formation of the source electrode 170s and the drain electrode 170d according to Embodiment 1, for example (see (p) of FIG. 4C).

This is how the thin-film transistor 300 can be manufactured.

[Conclusion]

As described above, the manufacturing method for a thin-film transistor according to the present embodiment includes: forming the oxide semiconductor film 341 above the substrate 310; forming the silicon film 351 on the oxide semiconductor film 341; and performing plasma oxidation on the silicon film 351 to (i) form the oxidized silicon film 352 and (ii) supply oxygen to the oxide semiconductor film 341.

Thus, the oxidized silicon film 352 formed by plasma oxidation protects a surface of the oxide semiconductor film 341 from damage due to plasma, and prevents the oxide semiconductor film 341 supplied with oxygen by plasma oxidation from being exposed to the air. Such a reduction in the occurrence of damage due to plasma and a reduction in oxygen loss allow a reduction in degradation of properties of the oxide semiconductor film 341.

As described above, the manufacturing method for a thin-film transistor according to the present embodiment makes it possible to reduce the oxygen loss, allowing the oxide semiconductor film 341 to have a reduced oxygen loss percentage. In other words, it is possible to reduce carrier sources in the oxide semiconductor film 341, and thus it is possible to decrease the resistance reduction, etc., of the oxide semiconductor film 341. Therefore, according to the present embodiment, the thin-film transistor 300 having less degraded electrical characteristics can be manufactured.

Note that the plasma oxidation allows the oxide semiconductor film 341 to be supplied with oxygen through the oxidized silicon film 352, and a lot of oxygen is therefore supplied to a region of the oxide semiconductor film 341 that faces the oxidized silicon film 352 contains oxygen. The region that faces the oxidized silicon film 352 is a region on the gate electrode 320 side, that is, the front channel region. Thus, in the case of the top-gate thin-film transistor 300, the resistance reduction of the front channel region is decreased, and therefore the degradation in electrical characteristics is further reduced.

### OTHER EMBODIMENTS

As described above, Embodiment 1 and Embodiment 2 are described as an exemplification of the technique disclosed in the present application. However, the technique according to the present disclosure is not limited to the foregoing embodiments, and can also be applied to embodiments to which a change, substitution, addition, or omission is executed as necessary.

For example, the above embodiments show an example of the plasma treatment in which surface wave plasma or capacitively coupled plasma having an excitation frequency of 27 MHz or more is used, but this is not the only example.

Furthermore, the bottom-gate and channel protective thin-film transistor is described in Embodiment 1, for example, but this may be a bottom-gate and channel-etched thin-film transistor.

Furthermore, the contact holes for the source electrode 170s and the drain electrode 170d are formed in the channel protective film 161 after the channel protective film 161 is formed over the entire surface as illustrated in (m) and (n) of FIG. 4C in Embodiment 1, for example, but this is not the only example. For example, the channel protective layer 160 that is previously patterned in a predetermined shape may be formed so as to expose the oxide semiconductor layer 140.

Specifically, in the process of forming the channel protective layer 160, it is sufficient that the channel protective layer 160 is formed in such a way that portions of the oxide semiconductor layer 140 is exposed. Likewise, in the process of forming the source electrode 170s and the drain electrode 170d, it is sufficient that the source electrode 170s and the drain electrode 170d are formed so as to connect to the oxide semiconductor layer 140 at the exposed portions.

The same applies to the formation of a layer which needs to be patterned in a predetermined shape, such as the oxide semiconductor layer 140. Specifically, the oxide semiconductor layer 140 that is previously patterned in a predetermined shape may be formed instead of being patterned after being formed over the entire surface. The same applies to the other embodiments.

Furthermore, in the above embodiments, the oxide semiconductor to be used in the oxide semiconductor layer is not limited to amorphous InGaZnO. For example, a polycrystalline semiconductor such as polycrystalline InGaO may be used.

Furthermore, in the above embodiments, an organic EL display device is described as a display device which includes a thin-film transistor, but the thin-film transistors in the above embodiments can be applied to other display devices, such as a liquid-crystal device, which include active-matrix substrates.

Furthermore, display devices (display panels) such as the above-described organic EL display device can be used as flat panel displays, and can be applied to various electronic devices having a display panel, such as television sets, personal computers, mobile phones, and so on. In particular, display devices (display panels) such as the above-described organic EL display device are suitable for large screen and high-definition display devices.

Moreover, embodiments obtained through various modifications to each embodiment and variation which may be conceived by a person skilled in the art as well as embodiments realized by arbitrarily combining the structural elements and functions of the embodiment and variation without materially departing from the spirit of the present disclosure are included in the present disclosure.

### INDUSTRIAL APPLICABILITY

The thin-film transistor and the manufacturing method for the same according to the present disclosure can be used, for example, in display devices such as organic EL display devices.

### REFERENCE SIGNS LIST

10 organic EL display device
20 TFT substrate
30 pixel
31 pixel circuit
32, 33, 100, 300 thin-film transistor
32d, 33d, 170d, 370d drain electrode
32g, 33g, 120, 320 gate electrode
32s, 33s, 170s, 370s source electrode
34 capacitor
40 organic EL element
41 anode
42 EL layer
43 cathode
50 gate line
60 source line
70 power supply line
110, 310 substrate
130, 330 gate insulating layer
140, 340 oxide semiconductor layer
141, 341 oxide semiconductor film
150, 153, 154, 350, 353, 354 silicon oxide layer
151, 351 silicon film
152, 352 oxidized silicon film
160 channel protective layer
161 channel protective film
171, 321, 371 metal film
180, 181, 380, 381 resist
200 film-forming device
210, 211 film-forming chamber
220 vacuum transportation chamber
230, 231, 232, 233 gate valve
331 gate insulating film
360 insulating layer
361 insulating film

1. A manufacturing method for a thin-film transistor, the method comprising:
forming an oxide semiconductor film above a substrate;
forming a silicon film on the oxide semiconductor film; and
performing plasma oxidation on the silicon film to (i) form an oxidized silicon film and (ii) supply oxygen to the oxide semiconductor film.

2. The manufacturing method for a thin-film transistor according to claim 1,
wherein in the forming of the silicon film, the silicon film is formed by sputtering.

3. The manufacturing method for a thin-film transistor according to claim 1,
wherein in the forming of the oxide semiconductor film and in the forming of the silicon film, the oxide semiconductor film and the silicon film are formed in a same vacuum system.

4. The manufacturing method for a thin-film transistor according to claim 1,
wherein the silicon film has a thickness of 5 nm or less.

5. The manufacturing method for a thin-film transistor according to claim 1,
wherein the silicon film has a thickness of 2 nm or more.

6. The manufacturing method for a thin-film transistor according to claim 1,
wherein in the performing of the plasma oxidation, the silicon film is oxidized with surface wave plasma or capacitively coupled plasma having an excitation frequency of 27 MHz or more.

7. The manufacturing method for a thin-film transistor according to claim 1, further comprising:
forming a resist on the oxidized silicon film, the resist being patterned;
forming a silicon oxide layer by dry-etching the oxidized silicon film using the resist as a mask, the silicon oxide layer being patterned;
wet-etching the oxide semiconductor film using the resist and the silicon oxide layer as a mask;
performing ashing to cause an edge of the resist to retreat; and
dry-etching the silicon oxide layer using the resist having a retreated edge as a mask.

8. The manufacturing method for a thin-film transistor according to claim 1,
wherein the oxide semiconductor film is a transparent amorphous oxide semiconductor.

9. The manufacturing method for a thin-film transistor according to claim 1,
wherein the oxide semiconductor film is InGaZnO.

10. A thin-film transistor comprising:
a substrate;
an oxide semiconductor layer formed above the substrate; and
a silicon oxide layer formed on the oxide semiconductor layer,
wherein the silicon oxide layer is formed by plasma oxidation of a silicon film formed on the oxide semiconductor layer, and
the oxide semiconductor layer contains oxygen supplied by the plasma oxidation.
